(19) United States
(12) Patent Application Publication
(10) Pub. No.: US 2024/0322076 A1
(43) Pub. Date: Sep. 26, 2024

(54) NITRIDE SEMICONDUCTOR LIGHT-EMITTING ELEMENT

(71) Applicant: NIKKISO CO., LTD., Tokyo (JP)

(72) Inventors: Cyril PERNOT, Ishikawa (JP); Yusuke MATSUKURA, Ishikawa (JP); Kazufumi TAKAO, Ishikawa (JP)

(73) Assignee: NIKKISO CO., LTD., Tokyo (JP)

(21) Appl. No.: 18/613,655

(22) Filed: Mar. 22, 2024

(30) Foreign Application Priority Data
Mar. 22, 2023 (JP) 2023-045022

(51) Int. Cl. H01L 33/14; H01L 33/06; H01L 33/32

(52) U.S. Cl. CPC H01L 33/145; H01L 33/06; H01L 33/32

(57) ABSTRACT

A nitride semiconductor light-emitting element includes an n-type semiconductor layer, an active layer that is formed on one side of the n-type semiconductor layer and includes a well layer and a barrier layer, an electron blocking layer that is formed on the active layer on an opposite side to the n-type semiconductor layer, and a p-type semiconductor layer formed on the electron blocking layer on an opposite side to the active layer. The electron blocking layer includes a plurality of semiconductor layers that are undoped. Among the plurality of semiconductor layers constituting the electron blocking layer, a first electron blocking layer located closest to the active layer has a higher Al composition ratio than that of the other semiconductor layers constituting the electron blocking layer and that of the barrier layer. A film thickness of the first electron blocking layer is less than 2 nm.

### CROSS-REFERENCE TO RELATED APPLICATIONS

The present application is based on Japanese patent application No. 2023-045022 filed on Mar. 22, 2023, the entire contents of which are incorporated herein by reference.

### TECHNICAL FIELD

The present invention relates to a nitride semiconductor light-emitting element.

### BACKGROUND OF THE INVENTION

Patent Literature 1 discloses a nitride semiconductor light-emitting element in which an n-side layer, an active layer, an electron blocking structure layer and a p-side layer are stacked. The electron blocking structure layer includes, from the active layer side, a first electron blocking layer, an intermediate layer, and a second electron blocking layer. The first electron blocking layer has a larger band gap than that of a barrier layer. The second electron blocking layer has a band gap larger than that of the barrier layer and smaller than that of the first electron blocking layer. The intermediate layer has a smaller band gap than that of the second electron blocking layer. Patent Literature 1 describes that the service life can be extended by forming the electron blocking structure layer so as to have the structure described above.
Citation List Patent Literature 1: WO 2017/057149

### SUMMARY OF THE INVENTION

For the configuration of the nitride semiconductor light-emitting element described in Patent Literature 1, however, there is room for improvement in terms of extending the service life.

The invention was made in view of such circumstances and it is an object of the invention to provide a nitride semiconductor light-emitting element that can achieve an extended service life.

To achieve the object described above, the invention provides a nitride semiconductor light-emitting element, comprising:
an n-type semiconductor layer comprising Al, Ga and N;
an active layer that is formed on one side of the n-type semiconductor layer and comprises a well layer comprising Al, Ga and N and a barrier layer comprising Al, Ga and N and having a higher Al composition ratio than that of the well layer;
an electron blocking layer that is formed on the active layer on an opposite side to the n-type semiconductor layer and comprises Al and N; and
a p-type semiconductor layer formed on the electron blocking layer on an opposite side to the active layer,
wherein the electron blocking layer comprises a plurality of semiconductor layers that are undoped,
wherein among the plurality of semiconductor layers constituting the electron blocking layer, a first electron blocking layer located closest to the active layer has a higher Al composition ratio than that of the other semiconductor layers constituting the electron blocking layer and that of the barrier layer, and
wherein a film thickness of the first electron blocking layer is less than 2 nm.

### Advantageous Effects of the Invention

According to the invention, it is possible to provide a nitride semiconductor light-emitting element that can achieve an extended service life.

### BRIEF DESCRIPTION OF DRAWINGS

FIG. 1 is a schematic diagram illustrating a configuration of a nitride semiconductor light-emitting element in an embodiment.

FIG. 2 is a graph showing silicon concentration distribution in the vicinity of an interface between an electron blocking layer and a p-type semiconductor layer in the nitride semiconductor light-emitting element in the embodiment.

FIG. 3 is a graph showing a relationship between current supply time and light output retention rate in Experimental Example 1.

FIG. 4 is a graph showing a relationship between film thickness of a first electron blocking layer and light output retention rate in Experimental Example 2.

FIG. 5 is a graph showing a relationship between film thickness of the first electron blocking layer and initial light output in Experimental Example 2.

FIG. 6 is a graph showing a relationship between film thickness of a p-type contact layer and light output retention rate in Experimental Example 3.

FIG. 7 is a graph showing a relationship between film thickness of the p-type contact layer and initial light output in Experimental Example 3.

### DETAILED DESCRIPTION OF THE INVENTION

### Embodiment

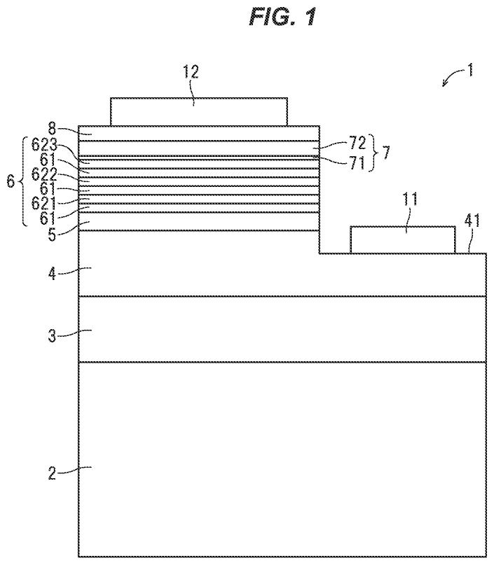

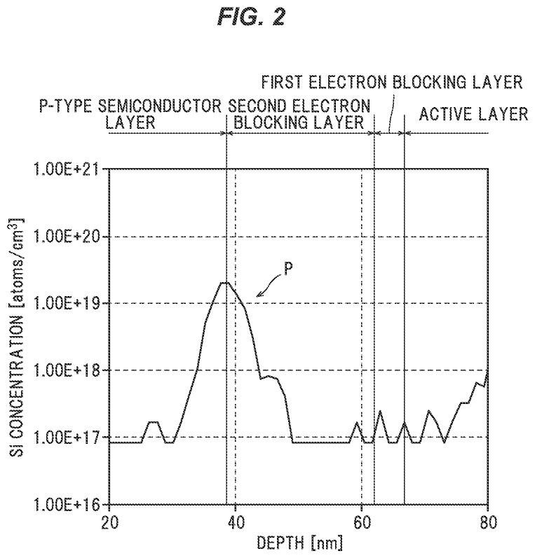

An embodiment of the invention will be described in reference to FIGS. 1 and 2. The embodiment below is described as a preferred illustrative example for implementing the invention. Although some part of the embodiment specifically illustrates various technically preferable matters, the technical scope of the invention is not limited to such specific aspects.

### Nitride Semiconductor Light-Emitting Element 1

FIG. 1 is a schematic diagram illustrating a configuration of a nitride semiconductor light-emitting element 1. In FIG. 1, the scale ratio in a direction of stacking each layer of the nitride semiconductor light-emitting element 1 (hereinafter, also simply referred to as “the light-emitting element 1”) is not necessarily the same as the actual scale ratio. Hereinafter, the direction of stacking each layer of the light-emitting element 1 is referred to as the up-and-down direction. In addition, one side in the up-and-down direction, which is a side of a substrate 2 where each semiconductor layer is grown, (e.g., an upper side in FIG. 1) will be referred to as the upper side, and the opposite side (e.g., a lower side in FIG. 1) will be referred to as the lower side. In this regard, the terms “upper” and “lower” are used for descriptive purposes and do not limit the posture of the light-emitting element 1 with respect to the vertical direction when, e.g., the light-emitting element 1 is used.

The light-emitting element 1 is, e.g., a light-emitting diode (LED) or a semiconductor laser (LD: laser diode). In the present embodiment, the light-emitting element 1 is a light-emitting diode that emits light with a wavelength in an ultraviolet region. Particularly, the light-emitting element 1 in the present embodiment emits ultraviolet light at a central wavelength of not less than 250 nm and not more than 365 nm. The light-emitting element 1 can be used in fields such as, e.g., sterilization (e.g., air purification, water purification, etc.), medical treatment (e.g., light therapy, measurement/analysis, etc.), UV curing, etc.

The light-emitting element 1 includes a buffer layer 3, an n-type cladding layer 4, a composition gradient layer 5, an active layer 6, an electron blocking layer 7 and a p-type semiconductor layer 8 in this order on the substrate 2. The light-emitting element 1 also includes an n-side electrode 11 provided on the n-type cladding layer 4, and a p-side electrode 12 provided on the p-type semiconductor layer 8.

As semiconductors constituting the light-emitting element 1, it is possible to use, e.g., binary to quaternary group III nitride semiconductors expressed by AlₐGa_{b}In_{1-a-b}N (0≤a≤1, 0≤b≤1, 0≤a+b≤1). In the present embodiment, binary or ternary group III nitride semiconductors expressed by Al_{c}Ga_{1-c}N (0≤c≤1) are used as the semiconductors constituting the light-emitting element 1. These group III elements may be partially substituted with boron (B) or thallium (Tl), etc. In addition, nitrogen (N) may be partially substituted with phosphorus (P), arsenic (As), antimony (Sb) or bismuth (Bi), etc.

The substrate 2 is made of a material transparent to light emitted by the active layer 6. The substrate 2 is, e.g., a sapphire (Al₂O₃) substrate. An upper surface of the substrate 2 (i.e., a surface on which each semiconductor layer of the light-emitting element 1 is stacked) is a c-plane. This c-plane may have an off-angle. Alternatively, e.g., an aluminum nitride (AlN) substrate or an aluminum gallium nitride (AlGaN) substrate, etc., may be used as the substrate 2.

The buffer layer 3 is formed on the substrate 2. In the present embodiment, the buffer layer 3 is made of aluminum nitride. When the substrate 2 is an aluminum nitride substrate or an aluminum gallium nitride substrate, the buffer layer 3 may not be necessarily included. The buffer layer 3 may also include a semiconductor layer made of undoped AlₚGa₁₋ₚN (0≤p≤1) that is formed on the semiconductor layer made of aluminum nitride.

The n-type cladding layer 4 is an n-type semiconductor layer formed on the buffer layer 3. The n-type cladding layer 4 is made of, e.g., Al_{q}Ga_{1-q}N (0≤q≤1) doped with an n-type impurity. In the present embodiment, silicon (Si) is used as the n-type impurity. Alternatively, germanium (Ge), selenium (Se) or tellurium (Te), etc., may be used as the n-type impurity. An Al composition ratio q of the n-type cladding layer 4 is, e.g., preferably not less than 20%, and is more preferably not less than 25% and not more than 70%. In this regard, the Al composition ratio is also called AlN mole fraction. A film thickness of the n-type cladding layer 4 can be, e.g., not less than 1 μm and not more than 4 μm. The n-type cladding layer 4 has a single layer structure in the present embodiment but may have a multilayer structure.

The composition gradient layer 5 is formed on the n-type cladding layer 4. The composition gradient layer 5 is made of AlᵣGa₁₋ᵣN (0≤r≤1) doped with silicon. An Al composition ratio of the composition gradient layer 5 along the up-and-down direction is higher as closer the active layer 6. The composition gradient layer 5 may include, e.g., a very small region in the up-and-down direction (e.g., a region of not more than 5% of the entire composition gradient layer 5 in the up-and-down direction) in which the Al composition ratio does not increase toward the active layer 6.

The Al composition ratio of an end portion of the composition gradient layer 5 on the n-type cladding layer 4 side is preferably substantially the same (e.g., a difference within 5%) as the Al composition ratio of an end portion of the n-type cladding layer 4 on the composition gradient layer 5 side. In addition, the Al composition ratio of an end portion of the composition gradient layer 5 on the active layer 6 side is preferably substantially the same (e.g., a difference within 5%) as an Al composition ratio of an end portion of the active layer 6 on the composition gradient layer 5 side. A film thickness of the composition gradient layer 5 can be, e.g., not less than 5 nm and not more than 50 nm.

The active layer 6 is formed on the composition gradient layer 5. The active layer 6 has a multi quantum well structure which includes plural well layers 621 to 623. A band gap of the active layer 6 is adjusted so that ultraviolet light at a central wavelength of not less than 250 nm and not more than 365 nm can be emitted.

In the present embodiment, the active layer 6 has three barrier layers 61 and three well layers 621 to 623, and the barrier layers 61 and the well layers 621 to 623 are alternately stacked. In the active layer 6, the barrier layer 61 is located at an end on the composition gradient layer 5 side and the well layer 623 is located at an end on the electron blocking layer 7 side. In this regard, the number of barrier layers 61 and the number of well layers 621 to 623 in the active layer 6 are not particularly limited.

Each barrier layer 61 is made of AlₛGa₁₋ₛN (0<s<1). An Al composition ratio s of each barrier layer 61 is, e.g., not less than 60% and not more than 100%. Each barrier layer 61 has a film thickness of, e.g., not less than 2 nm and not more than 50 nm.

The well layers 621 to 623 are made of AlₜGa₁₋ₜN (0<t<1). An Al composition ratio t of each of the well layers 621 to 623 is smaller than the Al composition ratio s of the barrier layers 61 (i.e., t<s).

In the present embodiment, the three well layers 621 to 623 will be referred to as a first well layer 621, a second well layer 622, and a third well layer 623 in order from the composition gradient layer 5 side. A film thickness of the first well layer 621 is not less than 1 nm greater than a film thickness of each of the second well layer 622 and the third well layer 623. This results in that each layer of the active layer 6 becomes flat and monochromaticity of output light is improved. A difference between the film thickness of the first well layer 621 and the film thickness of each of the second well layer 622 and the third well layer 623 is preferably not less than 2 nm and not more than 4 nm. Each of the second well layer 622 and the third well layer 623 has a film thickness of not less than 2 nm and not more than 4 nm and the first well layer 621 has a film thickness of not less than 4 nm and not more than 6 nm.

The Al composition ratio of the first well layer 621 is not less than 2% greater than the Al composition ratio of each of the second well layer 622 and the third well layer 623. By increasing the Al composition ratio of the first well layer 621 to higher than the Al composition ratio of each of the second well layer 622 and the third well layer 623, crystallinity of the first well layer 621 is improved. This is because the difference in the Al composition ratio between the first well layer 621 and the n-type cladding layer 4 is reduced. The improved crystallinity of the first well layer 621 improves crystallinity of each semiconductor layer formed on and above the first well layer 621 in the active layer 6. As a result, carrier mobility in the active layer 6 is improved and light output is improved. Such effects are more pronounced when the first well layer 621 has a larger film thickness, but the film thickness of the first well layer 621 is designed to be not more than a predetermined value from the viewpoint of suppressing an increase in the electrical resistance value of the entire light-emitting element 1.

In the present embodiment, each of the second well layer 622 and the third well layer 623 has an Al composition ratio of not less than 25% and not more than 45%, and the first well layer 621 has an Al composition ratio of not less than 35% and not more than 55%. The plural well layers 621 to 623 may be configured such that, e.g., the layer closer to the composition gradient layer 5 has a higher Al composition ratio.

The electron blocking layer 7 is formed on the active layer 6. The electron blocking layer 7 serves to improve efficiency of electron injection into the active layer 6 by suppressing occurrence of the overflow phenomenon in which electrons leak from the active layer 6 to the p-type semiconductor layer 8 side (hereinafter, also referred to as the electron blocking effect). In the present embodiment, the electron blocking layer 7 is made of undoped AlᵤG₁₋ᵤN (0.7≤u≤1). In other words, the electron blocking layer 7 is configured as a semiconductor layer with an Al composition ratio u of not less than 70%. The electron blocking layer 7 has a stacked structure in which a first electron blocking layer 71 and a second electron blocking layer 72 are stacked in this order from the active layer 6 side. The electron blocking layer 7 may be formed of not less than three layers.

The first electron blocking layer 71 is provided so as to be in contact with the active layer 6. Among the plural semiconductor layers (in the present embodiment, the first electron blocking layer 71 and the second electron blocking layer 72) constituting the electron blocking layer 7, the first electron blocking layer 71 has a higher Al composition ratio than that of the other semiconductor layers (i.e., the second electron blocking layer 72) constituting the electron blocking layer 7 and that of the barrier layers 61. The Al composition ratio of the first electron blocking layer 71 is, e.g., not less than 90% and may be 100% (i.e., the first electron blocking layer 71 may be made of AlN).

In the present embodiment, the first electron blocking layer 71 is formed extremely thin with a film thickness of less than 2 nm. As shown in Experimental Example 2 which will be described later, the service life of the light-emitting element 1 is extended by configuring the electron blocking layer 7 to be composed of plural undoped semiconductor layers and by forming the first electron blocking layer 71 to be extremely thin with a film thickness of less than 2 nm as described above. Also as shown in Experimental Example 2 which will be described later, the film thickness of the first electron blocking layer 71 is preferably less than 1.4 nm, more preferably not more than 1.0 nm, further preferably less than 1.0 nm, and most preferably not more than 0.8 nm, from the viewpoint of extending the service life of the light-emitting element 1. The film thickness of the first electron blocking layer 71 is also preferably not less than 0.5 nm from the viewpoint of ensuring initial light output.

The Al composition ratio of the second electron blocking layer 72 is lower than the Al composition ratio of the first electron blocking layer 71 and is, e.g., not less than 70% and not more than 90%. A film thickness of the second electron blocking layer 72 is larger than the film thickness of the first electron blocking layer 71. When the film thickness of the first electron blocking layer 71 is small, it increases the probability that electrons pass through the first electron blocking layer 71 from the active layer 6 side to the p-type semiconductor layer 8 side due to the tunnel effect, but this probability can be reduced by providing the second electron blocking layer 72.

A film thickness of the entire electron blocking layer 7 is preferably less than 70 nm. The electrical resistance value of the light-emitting element 1 increases as the film thickness of a semiconductor layer with a relatively high Al composition ratio, such as the electron blocking layer 7, increases, hence, the film thickness of the electron blocking layer 7 is preferably less than 70 nm.

Silicon is included between the electron blocking layer 7 and the p-type semiconductor layer 8. Magnesium is likely to be attracted to silicon and hydrogen is likely to bond to magnesium, hence, the presence of silicon between the electron blocking layer 7 and the p-type semiconductor layer 8 suppresses diffusion of magnesium and hydrogen from the p-type semiconductor layer 8 to the active layer 6 and the service life of the light-emitting element 1 is thereby extended. Furthermore, since silicon is included between the electron blocking layer 7 and the p-type semiconductor layer 8, a layer with pits (e.g., so-called V-pits) may be formed between the electron blocking layer 7 and the p-type semiconductor layer 8. Pits are formed by a silicon source being supplied to locations where dislocations exist. Therefore, by formation of pits, propagation of dislocations above the pits is suppressed and the service life of the light-emitting element 1 is extended.

FIG. 2 is a diagram illustrating silicon concentration distribution in the up-and-down direction in the light-emitting element 1 obtained by secondary ion mass spectrometry (SIMS). The depth on the horizontal axis in FIG. 2 represents a distance in the up-and-down direction from the surface of the p-type semiconductor layer 8 on the p-side electrode 12 side. When silicon is included between the electron blocking layer 7 and the p-type semiconductor layer 8, the silicon concentration distribution in the up-and-down direction in the light-emitting element 1 (hereinafter, also simply referred to as the “silicon concentration distribution”) determined by secondary ion mass spectrometry shows a peak P of the silicon concentration between the electron blocking layer 7 and the p-type semiconductor layer 8. When looking at the silicon concentration distribution, a tail portion, etc., of the peak P appears at the end portion of the electron blocking layer 7 on the p-type semiconductor layer 8 side and it looks as if silicon is included even though the electron blocking layer 7 is undoped, but this is a problem with SIMS measurement. Therefore, in case that silicon is included at the interface between the electron blocking layer 7 and the semiconductor layer adjacent thereto, it can be said that the electron blocking layer 7 is undoped as long as the silicon concentration is at the background level (e.g., a silicon concentration of not more than 5.0×10¹⁷ atoms/cm³) in the region of the electron blocking layer 7 excluding the range where the above-mentioned peak P appearing near the interface exists (e.g., the range from the position of the interface between the p-type semiconductor layer and the second electron blocking layer to a depth of around 50 nm) in the silicon concentration distribution obtained by SIMS measurement.

The p-type semiconductor layer 8 is formed on the electron blocking layer 7. The p-type semiconductor layer 8 is made of p-type AlᵥGa₁₋ᵥN (0≤v<0.7). That is, the p-type semiconductor layer 8 is configured as a semiconductor layer with an Al composition ratio of less than 70%.

The p-type semiconductor layer 8 has a p-type contact layer. The p-type contact layer is a layer connected to the p-side electrode 12 and is made of AlᵥGa₁₋ᵥN (0≤v<0.7) doped with a high concentration of a p-type impurity. The p-type contact layer is configured to have a low Al composition ratio to achieve an ohmic contact with the p-side electrode 12 and, from such a viewpoint, is preferably made of p-type gallium nitride. Semiconductor layers made of p-type gallium nitride are likely to absorb ultraviolet light. Therefore, from the viewpoint of preventing absorption of ultraviolet light and improving light output of the light-emitting device 1, a film thickness of the p-type contact layer is preferably not more than 25 nm. Also from the viewpoint of extending the service life of the light-emitting element 1, the film thickness of the p-type contact layer is preferably not more than 25 nm, more preferably not more than 18 nm, as shown in Experimental Example 3 which will be described later. Further, from the viewpoint of suppressing occurrence of short circuits, the film thickness of the p-type contact layer is preferably not less than 5 nm.

The p-type semiconductor layer 8 may further include a p-type cladding layer on the electron blocking layer 7 side of the p-type contact layer. The p-type cladding layer is made of p-type AlGaN with an Al composition ratio of less than 70%. The p-type cladding layer may be composed of, e.g., a single layer or may be composed of plural layers. When the p-type cladding layer is composed of plural layers, the p-type cladding layer may have, e.g., a first p-type cladding layer formed on the second electron blocking layer 72 side and a second p-type cladding layer formed between the first p-type cladding layer and the p-type contact layer. An Al composition ratio of the second p-type cladding layer along the up-and-down direction may be such that the closer to the p-type contact layer, the lower the Al composition ratio. The second p-type cladding layer may include, e.g., a very small region in the up-and-down direction (e.g., a region of not more than 5% of the entire second p-type cladding layer in the up-and-down direction) in which the Al composition ratio does not increase toward the p-type contact layer. The Al composition ratio of an end portion of the second p-type cladding layer on the first p-type cladding layer side is preferably substantially the same (e.g., a difference within 5%) as an Al composition ratio of an end portion of the first p-type cladding layer on the second p-type cladding layer side. In addition, the Al composition ratio of an end portion of the second p-type cladding layer on the p-type contact layer side is preferably substantially the same (e.g., a difference within 5%) as the Al composition ratio of an end portion of the p-type contact layer on the second p-type cladding layer side.

The total optical film thickness of the semiconductor layers present above the active layer 6 (i.e., the electron blocking layer 7 and the p-type semiconductor layer 8) in the light-emitting device 1 is preferably designed so that light emitted upward from the active layer 6, reflected at the p-side electrode 12 and travelling downward and light directly emitted downward from the active layer 6 amplify each other. When a central wavelength of the light emitted from the active layer 6 is defined as a wavelength λ [nm], the total optical film thickness of the semiconductor layers present above the active layer 6 is, e.g., preferably not less than 0.5λ and not more than 1.4λ, more preferably not less than 0.5λ and not more than 0.8λ or not less than 1.0λ and not more than 1.3λ, even more preferably not less than 0.5λ and not more than 0.8λ.

The n-side electrode 11 is formed on an exposed surface 41 that is formed on the upper side of the n-type cladding layer 4 and is exposed from the active layer 6. The n-side electrode 11 can be, e.g., a multilayered film formed by sequentially stacking titanium (Ti), aluminum, titanium and gold (Au) on the n-type cladding layer 4. When the light-emitting element 1 is flip-chip mounted as described below, the n-side electrode 11 may be composed of a material that can reflect ultraviolet light emitted by the active layer 6.

The p-side electrode 12 is formed on an upper surface of the p-type semiconductor layer 8. The p-side electrode 12 can be made of, e.g., indium tin oxide (ITO), etc. When the light-emitting element 1 is flip-chip mounted as described below, the p-side electrode 12 may be composed of a material that can reflect ultraviolet light emitted by the active layer 6.

The light-emitting element 1 can be used in a state of being flip-chip mounted on a package substrate (not shown). That is, the light-emitting element 1 is mounted such that a side in the up-and-down direction, which is a side where the n-side electrode 11 and the p-side electrode 12 are provided, faces the package substrate and each of the n-side electrode 11 and the p-side electrode 12 is attached to the package substrate via a gold bump, etc. Light from the flip-chip mounted light-emitting element 1 is extracted on the substrate 2 side. However, it is not limited thereto and the light-emitting element 1 may be mounted on the package substrate by wire bonding, etc. In addition, although the light-emitting element 1 in the present embodiment is the light-emitting element 1 of so-called lateral type in which both the n-side electrode 11 and the p-side electrode 12 are provided on the upper side of the light-emitting element 1, it is not limited thereto and the light-emitting element 1 may be of the vertical type. The vertical light-emitting element 1 is the light-emitting element 1 in which the active layer 6 is sandwiched between the n-side electrode 11 and the p-side electrode 12. In this regard, when the light-emitting element 1 is of the vertical type, the substrate 2 and the buffer layer 3 are preferably removed by laser lift-off, etc.

### Method for Manufacturing the Light-Emitting Element 1

Next, an example of a method for manufacturing the light-emitting element 1 in the present embodiment will be described.

In the present embodiment, the buffer layer 3, the n-type cladding layer 4, the composition gradient layer 5, the active layer 6, the electron blocking layer 7 and the p-type semiconductor layer 8 are epitaxially grown on the disc-shaped substrate 2 in this order by the Metal Organic Chemical Vapor Deposition (MOCVD) method. That is, in the present embodiment, the disc-shaped substrate 2 is placed in a pocket of a susceptor arranged in a chamber and each semiconductor layer is formed on the substrate 2 by introducing source gases of each semiconductor layer to be formed on the substrate 2 into the chamber. The MOCVD method is sometimes called the Metal Organic Vapor Phase Epitaxy (MOVPE) method.

As the source gases to epitaxially grow each layer, it is possible to use trimethylaluminum (TMA) as an aluminum source, trimethylgallium (TMG) as a gallium source, ammonia (NH₃) as a nitrogen source, tetramethylsilane (TMSi) as a silicon source, and biscyclopentadienylmagnesium (Cp₂Mg) as a magnesium source. Regarding the manufacturing conditions for epitaxially growing each semiconductor layer of wafer, such as growth temperature, growth pressure and growth time, etc., it is possible to appropriately adopt the conditions according to the configuration of each semiconductor layer.

To epitaxially grow each semiconductor layer on the substrate 2, it is also possible to use another epitaxial growth method such as the Molecular Beam Epitaxy (MBE) method or the Hydride Vapor Phase Epitaxy (HVPE) method.

After forming each semiconductor layer on the disc-shaped substrate 2, a mask is formed on a portion of the p-type semiconductor layer 8, i.e., a part other than the portion to be the exposed surface 41 of the n-type cladding layer 4. Then, the region in which the mask is not formed is removed by etching from the upper surface of the p-type semiconductor layer 8 to the middle of the n-type cladding layer 4 in the up-and-down direction. The exposed surface 41 exposed upward is thereby formed on the n-type cladding layer 4. After forming the exposed surface 41, the mask is removed.

Subsequently, the n-side electrode 11 is formed on the exposed surface 41 of the n-type cladding layer 4 and the p-side electrode 12 is formed on the p-type semiconductor layer 8. The n-side electrode 11 and the p-side electrode 12 may be formed by, e.g., a well-known method such as the electron beam evaporation method or the sputtering method. The object completed through the above process is cut into pieces with a desired dimension. Plural light-emitting elements 1 as shown in FIG. 1 are thereby obtained from one wafer.

### Functions and Effects of the Embodiment

In the light-emitting device 1 of the present embodiment, the electron blocking layer 7 is composed of plural undoped semiconductor layers. Among the plural semiconductor layers constituting the electron blocking layer 7, the first electron blocking layer 71 located closest to the active layer has a higher Al composition ratio than that of the other semiconductor layers (i.e., the second electron blocking layer 72 in the present embodiment) constituting the electron blocking layer 7 and that of the barrier layers 61. Then, the film thickness of the first electron blocking layer is less than 2 nm. The service life of the light-emitting element 1 can thereby be extended, as shown in Experimental Example 2 described later. Moreover, by setting the film thickness of the first electron blocking layer 71 to further satisfy less than 1.4 nm, the service life of the light-emitting element 1 can be further extended, as shown in Experimental Example 2 described later.

In addition, the p-type semiconductor layer 8 has the p-type contact layer made of p-type gallium nitride (GaN) and the film thickness of the p-type contact layer is not more than 25 nm. The service life of the light-emitting element 1 can thereby be extended, as shown in Experimental Example 3 described later. Moreover, by setting the film thickness of the p-type contact layer to not more than 18 nm, the service life of the light-emitting element 1 can be further extended, as shown in Experimental Example 3 described later.

In addition, silicon is included at the interface between the electron blocking layer 7 and the p-type semiconductor layer 8. Magnesium is likely to be attracted to silicon and hydrogen is likely to bond to magnesium, hence, the presence of silicon between the electron blocking layer 7 and the p-type semiconductor layer 8 suppresses diffusion of magnesium and hydrogen from the p-type semiconductor layer 8 to the active layer 6 and the service life of the light-emitting element 1 is thereby extended. Furthermore, since silicon is included between the electron blocking layer 7 and the p-type semiconductor layer 8, a layer with pits may be formed between the electron blocking layer 7 and the p-type semiconductor layer 8. Pits are formed by a silicon source being supplied to locations where dislocations exist. Therefore, by formation of pits, propagation of dislocations above the pits is suppressed and the service life of the light-emitting element 1 is extended.

As described above, according to the present embodiment, it is possible to provide a nitride semiconductor light-emitting element that can achieve an extended service life.

### Experimental Example 1

Experimental Example 1 is an example in which change in light output retention rate over time was evaluated for two light-emitting elements that have the same basic structure as the light-emitting element described in the embodiment but are different in the film thickness of the first electron blocking layer. The light output retention rate is a ratio of the light output of the light-emitting element after a given time of current supply to the initial light output of the light-emitting element. Among the terms used in Experimental Example 1 onwards, the same terms as those used in the above-mentioned embodiment indicate the same contents as those in the above-mentioned embodiment, unless otherwise specified.

In this Experimental Example 1, a light-emitting element in which the first electron blocking layer has a film thickness of 0.8 nm was prepared as Example A1, and a light-emitting element in which the first electron blocking layer has a film thickness of 1.6 nm was prepared as Example A2. That is, in both Examples A1 and A2, the film thickness of the first electron blocking layer satisfies less than 2 nm as in the same manner as the embodiment. Each of Examples A1 and A2 is a packaged light-emitting element. The structure, the film thickness of each layer, the Al composition ratio of each layer and the silicon concentration in each layer for Examples A1 and A2 are shown in Table 1 below.

TABLE 1

| | | Film | | Al composition | Si concentration |
|---|---|---|---|---|---|
| Structure (Examples A1, A2) | | thickness | | ratio [%] | [atoms/cm³] |
| Substrate | | 430 ± | 25 [um] | — | BG |
| Buffer layer | | 2000 ± | 200 [nm] | 100 | |
| N-type semiconductor layer | | 2000 ± | 200 [nm] | 55 ± 10 | (1.50 ± 1.00)E+19 |
| Composition gradient layer | | 15 ± | 5 [nm] | 55→85 | BG - Peak concentration |
| Active layer | Barrier layer | 7 ± | 5 [nm] | 85 ± 10 | in First well layer* |
| (3QW) | First well layer | 5 ± | 1 [nm] | 45 ± 10 | (3.50 ± 2.50)E+19 |
| | | | | | (Peak concentration) |
| | Barrier layer | 7 ± | 5 [nm] | 85 ± 10 | BG - Peak concentration |
| | | | | | in First well layer* |
| | Second well layer | 3 ± | 1 [nm] | 35 ± 10 | BG - 1.00E+19* |
| | Barrier layer | 7 ± | 5 [nm] | 85 ± 10 | |
| | Third well layer | 3 ± | 1 [nm] | 35 ± 10 | BG - 1.00E+18* |
| Electron | First electron blocking layer | Example A1: | | 95 ± 5 | BG |
| blocking | | 0.8 [nm] | | | |
| layer | | Example A2: | | | |
| | | 1.6 [nm] | | | |
| | Second electron blocking | 25 ± | 10 [nm] | 80 ± 10 | BG |
| | layer | | | | (Peak concentration at |
| | | | | | Interface between |
| | | | | | Electron blocking layer |
| P-type | First p-type cladding layer | 25 ± | 10 [nm] | 55 ± 10 | and P-type |
| semiconductor | | | | | semiconductor layer: |
| layer | | | | | (2.00 ± 1.00)E+19) |
| | Second p-type cladding layer | 3 ± | 1 [nm] | 55→0 | BG |

| | | | |
|---|---|---|---|
| P-type contact layer | 22 [nm] | 0 | BG |

The film thickness of each layer shown in Table 1, except for the film thickness of the first electron blocking layer, was measured by a transmission electron microscope (TEM: Transmission Electron Microscopy). The film thickness of the first electron blocking layer shown in Table 1 will be described later. The Al composition ratio of each layer shown in Table 1 is a value estimated from secondary ion intensity of Al measured by secondary ion mass spectrometry. The figures in the column of Al composition ratio for Composition gradient layer in Table 1 show that the Al composition ratio of the composition gradient layer along the up-and-down direction changes from 55% to 85% from the n-type cladding layer side to the active layer side. Likewise, the figures in the column of Al composition ratio for Second p-type cladding layer in Table 1 show that the Al composition ratio of the second p-type cladding layer along the up-and-down direction changes from 55% to 0% from the first p-type cladding layer side to the p-type contact layer side. The silicon concentration in each layer shown in Table 1 was obtained using secondary ion mass spectrometry. In Table 1, each part marked with “*” in the column of Si concentration means that the film thickness of the semiconductor layer is small and it is difficult to accurately measure the silicon concentration. In addition, “BG” in the column of Si concentration in Table 1 means the background level. The background-level silicon concentration is a silicon concentration that would be detected when not doped with silicon, specifically a silicon concentration of not more than 5.0×10¹⁷ atoms/cm³.

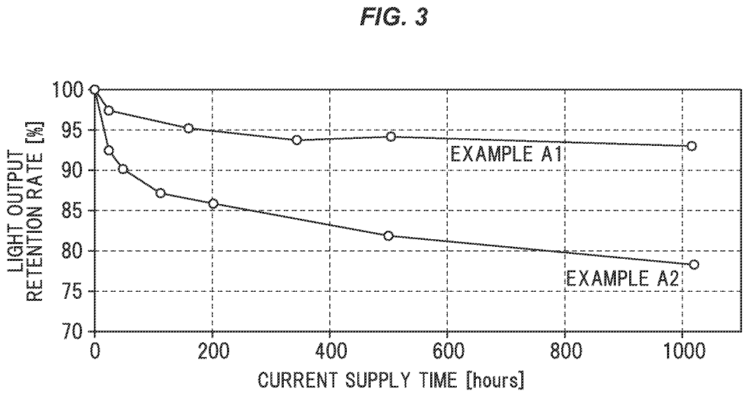

Then, a current of 500 mA was continuously passed through each of Examples A1 and A2 until a cumulative total time becomes more than 1000 hours, while evaluating the light output retention rate at multiple points in time. The results are shown in FIG. 3.

As can be seen from FIG. 3, in both Examples A1 and A2, the light output retention rate after 1000 hours of current supply is more than 70%. Here, generally, the light output retention rate of light-emitting elements after 1000 hours of current supply is required to be not less than 70%. This requirement is satisfied in Examples A1 and A2 in which the film thickness of the first electron blocking layer is less than 2 nm.

It can be also seen from FIG. 3 that Example A1 in which the film thickness of the first electron blocking layer is relatively small has a longer service life than Example A2 in which the film thickness of the first electron blocking layer is relatively large.

In both Examples A1 and A2, the light output retention rate decreases significantly until reaching the current supply time of 100 hours, and after that, the decrease in the light output retention rate slows down. Even in Example A2 in which a difference between the light output retention rate at 100 hours of current supply and the light output retention rate at 1000 hours of current supply is relatively large, the difference was about 10%. Therefore, in case of light-emitting elements in which the film thickness of the first electron blocking layer is less than 2 nm, the light output retention rate at 1000 hours of current supply is expected to be more than 70% if the light output retention rate at 100 hours of current supply is more than 80%. By taking into account this result, the relationship between the film thickness of the first electron blocking layer and the retention rate of the light-emitting element at 100 hours of current supply was evaluated in the next Experimental Example 2.

### Experimental Example 2

Experimental Example 2 is an example in which the relationship between the film thickness of the first electron blocking layer and the light output retention rate at 100 hours of current supply was evaluated for light-emitting elements having the same basic configuration as in the embodiment.

In this Experimental Example 2, light-emitting elements in which the first electron blocking layer has a film thickness of 1.6 nm were prepared as Examples B1 to B10, light-emitting elements in which the first electron blocking layer has a film thickness of 1.2 nm were prepared as Examples B11 and B12, light-emitting elements in which the first electron blocking layer has a film thickness of 1.0 nm were prepared as Examples B13 and B14, and light-emitting elements in which the first electron blocking layer has a film thickness of 0.8 nm were prepared as Examples B15 to B18. Examples B1 to B18 are packaged light-emitting elements. The structure, the film thickness of each layer, the Al composition ratio of each layer and the silicon concentration in each layer for Examples B1 to B18 are the same as those shown in Table 1 of Experimental Example 1, except for the film thickness of the first electron blocking layer.

First, initial light output of each Example was measured by passing a current of 350 mA. Then, a current of 500 mA was continuously passed through each Example for 100 hours for light emission. After that, light output of each Example after 100 hours of current supply was measure by passing a current of 350 mA, and the light output retention rate was calculated.

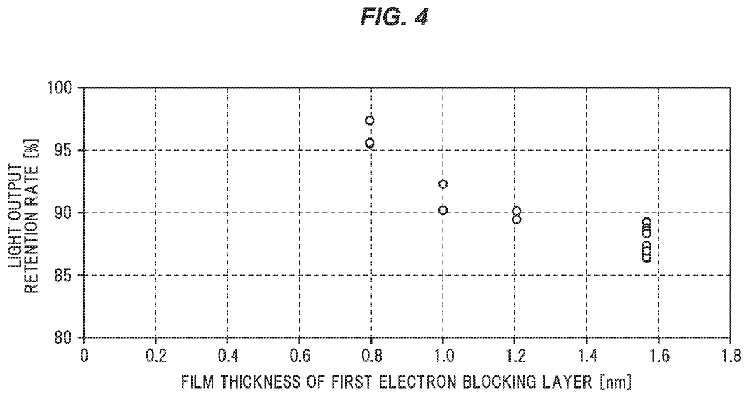

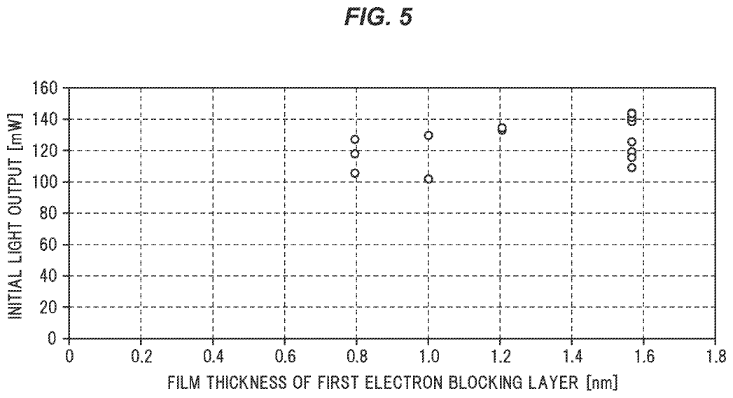

The film thickness of the first electron blocking layer, the initial light output and the retention rate for each Example are shown in Table 2. In addition, the relationship between the film thickness of the first electron blocking layer and the light output retention rate for each Example is shown in FIG. 4, and the relationship between the film thickness of the first electron blocking layer and the initial light output is shown in FIG. 5. Here, the light output retention rate of each Example shown in Table 2 and FIG. 4 is an average of the light output retention rates obtained from ten packaged light-emitting elements made from one wafer. Likewise, the initial light output of each Example shown in Table 2 and FIG. 5 is an average of the initial light outputs measured on the ten light-emitting elements.

TABLE 2

| | Film thickness of First | Initial light | Light output |
|---|---|---|---|
| | electron blocking layer | output | retention rate |
| Examples | [nm] | [mW] | [%] |
| B1 | 1.6 | 119.0 | 86 |
| B2 | 1.6 | 140.1 | 89 |
| B3 | 1.6 | 109.1 | 87 |
| B4 | 1.6 | 119.3 | 87 |
| B5 | 1.6 | 115.7 | 86 |
| B6 | 1.6 | 125.6 | 87 |
| B7 | 1.6 | 138.5 | 87 |
| B8 | 1.6 | 144.0 | 89 |
| B9 | 1.6 | 141.2 | 89 |
| B10 | 1.6 | 143.6 | 88 |
| B11 | 1.2 | 133.0 | 90 |
| B12 | 1.2 | 134.5 | 89 |
| B13 | 1.0 | 129.7 | 92 |
| B14 | 1.0 | 101.9 | 90 |
| B15 | 0.8 | 105.5 | 97 |
| B16 | 0.8 | 127.2 | 95 |
| B17 | 0.8 | 117.9 | 96 |
| B18 | 0.8 | 105.7 | 96 |

As can be seen from Table 2 and FIG. 4, in all Examples B1 to B18 in which the film thickness of the first electron blocking layer satisfies less than 2 nm, the light output retention rate after 100 hours of current supply is not less than 85%, which means that a high light output retention rate is obtained. The light output retention rate after 100 hours of current supply is preferably more than 80% for light-emitting elements in which the film thickness of the first electron blocking layer satisfies less than 2 nm as described in Experimental Example 1, and Examples B1 to B18 sufficiently satisfy this requirement.

In addition, as can be seen from Table 2 and FIG. 4, the film thickness of the first electron blocking layer 71 is preferably, is preferably less than 1.4 nm, more preferably not more than 1.0 nm, further preferably less than 1.0 nm, and most preferably not more than 0.8 nm, from the viewpoint of obtaining a high light output retention rate.

In addition, as can be seen from Table 2 and FIG. 5, satisfactory initial light output is obtained in all Examples B1 to B18 in which the film thickness of the first electron blocking layer is less than 2 nm.

### Experimental Example 3

Experimental Example 3 is an example in which the relationship between the film thickness of the p-type contact layer and the light output retention rate at 100 hours of current supply was evaluated for light-emitting elements having the same basic configuration as in the embodiment.

In this Experimental Example 3, five light-emitting elements which are different in the film thickness of the p-type contact layer were prepared as Examples C1 to C5. Examples C1 to C5 are packaged light-emitting elements. The structure, the film thickness of each layer, the Al composition ratio of each layer and the silicon concentration in each layer for Examples C1 to C5 are the same as those shown in Table 1 of Experimental Example 1, except for the film thickness of the p-type contact layer. In all of Examples C1-C5, the film thickness of the first electron blocking layer was 1.6 nm.

The light output retention rate of each Example was calculated in the same manner as in Experimental Example 2. That is, first, initial light output of each Example was measured by passing a current of 350 mA. Then, a current of 500 mA was continuously passed through each Example for 100 hours for light emission. After that, light output of each Example after 100 hours of current supply was measure by passing a current of 350 mA, and the light output retention rate was calculated.

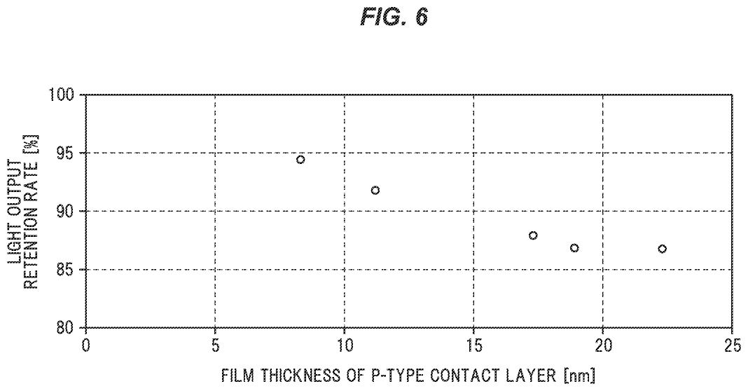

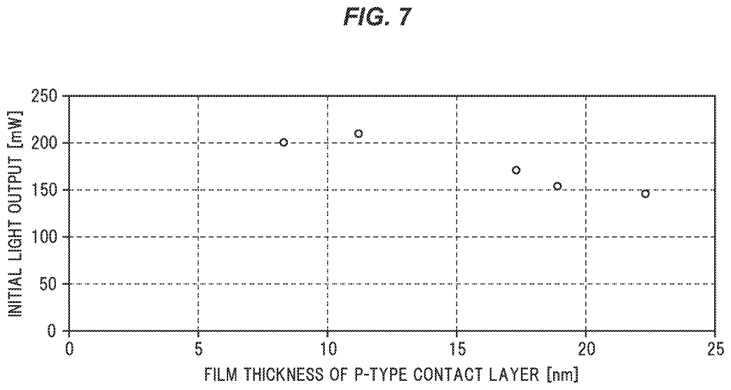

The film thickness of the p-type contact layer, the initial light output and the light output retention rate for each Example are shown in Table 3, the relationship between the film thickness of the p-type contact layer and the light output retention rate for each Example is shown in FIG. 6, and the relationship between the film thickness of the p-type contact layer and the initial light output is shown in FIG. 7.

TABLE 3

| | Film thickness of P-type | Initial light | Light output |
|---|---|---|---|
| | contact layer | output | retention rate |
| Examples | [nm] | [mW] | [%] |
| C1 | 22.3 | 145.9 | 87 |
| C2 | 18.9 | 154.0 | 87 |
| C3 | 17.3 | 171.0 | 88 |
| C4 | 11.2 | 209.9 | 92 |
| C5 | 8.3 | 200.5 | 94 |

As can be seen from Table 3 and FIG. 6, in all Examples C1 to C5 in which the film thickness of the p-type contact layer satisfies not more than 25 nm, the light output retention rate after 100 hours of current supply is not less than 85%, which means that a high light output retention rate is obtained. The light output retention rate after 100 hours of current supply is preferably more than 80% for light-emitting elements in which the film thickness of the first electron blocking layer satisfies less than 2 nm as described in Experimental Example 1, and Examples C1 to C5 sufficiently satisfy this requirement.

In addition, as can be seen from Table 3 and FIG. 6, the film thickness of the p-type contact layer is preferably not more than 18 nm, more preferably not more than 15 nm, from the viewpoint of obtaining a high light output retention rate.

In addition, as can be seen from Table 3 and FIG. 7, the film thickness of the p-type contact layer is preferably not more than 18 nm, more preferably not less than 5 nm and not more than 15 nm, from the viewpoint of improving the initial light output.

### SUMMARY OF THE EMBODIMENT

Technical ideas understood from the embodiment will be described below citing the reference signs, etc., used for the embodiment. However, each reference sign, etc., described below is not intended to limit the constituent elements in the claims to the members, etc., specifically described in the embodiment.

The first feature of the invention is a nitride semiconductor light-emitting element 1, comprising: an n-type semiconductor layer 4 comprising Al, Ga and N; an active layer 6 that is formed on one side of the n-type semiconductor layer 4 and comprises a well layer 621-623 comprising Al, Ga and N and a barrier layer 61 comprising Al, Ga and N and having a higher Al composition ratio than that of the well layer 621-623; an electron blocking layer 7 that is formed on the active layer 6 on an opposite side to the n-type semiconductor layer 4 and comprises Al and N; and a p-type semiconductor layer 8 formed on the electron blocking layer 7 on an opposite side to the active layer 6, wherein the electron blocking layer 7 comprises a plurality of semiconductor layers that are undoped, wherein among the plurality of semiconductor layers constituting the electron blocking layer 7, a first electron blocking layer 71 located closest to the active layer 6 has a higher Al composition ratio than that of the other semiconductor layers constituting the electron blocking layer 7 and that of the barrier layer 6, and wherein a film thickness of the first electron blocking layer 71 is less than 2 nm.

It is thereby possible to extend the service life of the light-emitting element 1.

The second feature of the invention is that, in the first feature, the film thickness of the first electron blocking layer 7 is less than 1.4 nm.

It is thereby possible to extend the service life of the light-emitting element 1.

The third feature of the invention is that, in the first or second feature, the p-type semiconductor layer 8 comprises a p-type contact layer comprising p-type GaN, and wherein a film thickness of the p-type contact layer is not more than 25 nm.

It is thereby possible to extend the service life of the light-emitting element 1.

The fourth feature of the invention is that, in the third feature, the film thickness of the p-type contact layer is not more than 18 nm.

It is thereby possible to extend the service life of the light-emitting element 1.

The fifth feature of the invention is that, in any one of the first to fourth features, silicon is included at an interface between the electron blocking layer 7 and the p-type semiconductor layer 8.

It is thereby possible to extend the service life of the light-emitting element 1.

### ADDITIONAL NOTE

Although the embodiment of the invention has been described, the invention according to claims is not to be limited to the embodiment described above. Further, please note that not all combinations of the features described in the embodiment are necessary to solve the problem of the invention. In addition, the invention can be appropriately modified and implemented without departing from the gist thereof.

1. A nitride semiconductor light-emitting element, comprising:
an n-type semiconductor layer comprising Al, Ga and N;
an active layer that is formed on one side of the n-type semiconductor layer and comprises a well layer comprising Al, Ga and N and a barrier layer comprising Al, Ga and N and having a higher Al composition ratio than that of the well layer;
an electron blocking layer that is formed on the active layer on an opposite side to the n-type semiconductor layer and comprises Al and N; and
a p-type semiconductor layer formed on the electron blocking layer on an opposite side to the active layer,
wherein the electron blocking layer comprises a plurality of semiconductor layers that are undoped,
wherein among the plurality of semiconductor layers constituting the electron blocking layer, a first electron blocking layer located closest to the active layer has a higher Al composition ratio than that of the other semiconductor layers constituting the electron blocking layer and that of the barrier layer, and
wherein a film thickness of the first electron blocking layer is less than 2 nm.

2. The nitride semiconductor light-emitting element according to claim 1, wherein the film thickness of the first electron blocking layer is less than 1.4 nm.

3. The nitride semiconductor light-emitting element according to claim 1, wherein the p-type semiconductor layer comprises a p-type contact layer comprising p-type GaN, and wherein a film thickness of the p-type contact layer is not more than 25 nm.

4. The nitride semiconductor light-emitting element according to claim 3, wherein the film thickness of the p-type contact layer is not more than 18 nm.

5. The nitride semiconductor light-emitting element according to claim 1, wherein silicon is included at an interface between the electron blocking layer and the p-type semiconductor layer.
